(19) United States
(12) Patent Application Publication
(10) Pub. No.: US 2007/0228450 A1
(43) Pub. Date: Oct. 4, 2007

(54) FLASH MEMORY DEVICE WITH ENLARGED CONTROL GATE STRUCTURE, AND METHODS OF MAKING SAME

(76) Inventors: Di Li, Boise, ID (US); Chandra Mouli, Boise, ID (US)

Correspondence Address: WILLIAMS, MORGAN & AMERSON, 10333 RICHMOND, SUITE 1100, HOUSTON, TX, 77042, US

(21) Appl. No.: 11/277,823

(22) Filed: Mar. 29, 2006

(51) Int. Cl. H01L 29/788; H01L 21/8238

(52) U.S. Cl. 257/315; 438/211; 257/317; 257/E29.129

(57) ABSTRACT

Disclosed is a flash memory device with an enlarged control gate structure, and various methods of make same. In one illustrative embodiment, the device includes a plurality of floating gate structures formed above a semiconducting substrate, an isolation structure positioned between each of the plurality of floating gate structures and a control gate structure comprising a plurality of enlarged end portions, each of the enlarged end portions being positioned between adjacent floating gate structures.

### BACKGROUND OF THE INVENTION

1. Field of the Invention

The present invention is generally directed to the field of integrated circuit devices, and, more particularly, to a flash memory device with an enlarged control gate structure, and various methods of make same.

2. Description of the Related Art

Manufacturing integrated circuit devices is a very competitive and complex undertaking. Customers frequently demand that such integrated circuit devices exhibit increased performance capabilities as successive generations of products are produced. This is particularly true in the field of manufacturing memory devices, such as flash memory devices.

FIG. 1 is a cross-sectional view of an illustrative flash memory device 10 taken along the longitudinal axis of the word line 28. As shown therein, a plurality of isolation structures 14, e.g., trench isolation structures, are formed in a semiconducting substrate 12. The substrate 12 may take a variety of forms, e.g., a bulk silicon substrate, a layer of epitaxially grown semiconducting material, etc. The device 10 has a gate stack 20 comprised of a so-called tunnel oxide layer 22, a floating gate 24, an inter-gate or inter-poly layer 26 (e.g., an ONO (oxide-nitride-oxide) stack), and the control gate 28. Note that the control gate 28 depicted in FIG. 1 also has downwardly extending fingers 32 positioned between adjacent floating gate structures 24.

In operation, a voltage is applied to the control gate 28 and to the source region (not shown) and/or channel region of the device 10. Such voltage causes electrons to tunnel through the tunnel oxide layer 22 and become trapped in the floating gate 24. The presence or absence of this trapped charge can be detected and represents a bit of information, i.e., a “1” or a “0”. To remove this charge, a different voltage is applied to the control gate 28 and a drain region (not shown) and/or channel region. During this process, the electrons trapped in the floating gate 24 tunnel back through the tunnel oxide layer 22, thereby depleting the charge on the floating gate 24.

The control gate 28 is capacitively coupled to the floating gate 24 so as to control the voltage applied to the floating gate 24. This capacitive coupling is very important. The downward-extending fingers 32 of the control gate 28 assist in providing or enhancing this capacitive coupling.

FIG. 2 depicts another illustrative memory device 30 that has the same basic structure as that of the device 10 shown in FIG. 1. However, in the device 30, the control gate 28 has elongated fingers 33 that are positioned between adjacent gate electrode structures 24. The fingers 33 are elongated in the sense that the fingers 33 extend partially into the isolation structure 14. The elongated fingers 33 tend to increase the capacitive coupling between the control gate 28 and the floating gate 24. Additionally, the elongated fingers 33 tend to provide some degree of shielding between adjacent floating gate structures 24. The purpose of the shielding is to attempt to prevent interference between the floating gates.

Despite the advances made by the structures depicted in FIGS. 1 and 2, improvements in the capacitive coupling between the control gate and floating gate of a flash memory device are still needed. Additionally, improved shielding between adjacent floating gate structures is always desired.

The present invention is directed to a device and various methods that may solve, or at least reduce, some or all of the aforementioned problems.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

The present invention is generally directed to a flash memory device with an enlarged control gate structure, and various methods of make same. In one illustrative embodiment, the device comprises a plurality of floating gate structures formed above a semiconducting substrate, an isolation structure positioned between each of the plurality of floating gate structures and a control gate structure comprising a plurality of enlarged end portions, each of the enlarged end portions being positioned between adjacent floating gate structures.

In another illustrative embodiment, the device comprises a plurality of floating gate structures formed above a semiconducting substrate, an isolation structure positioned between each of the plurality of floating gate structures, wherein each of the floating gate structures comprises overhang portions that are positioned above adjacent isolation structures, and a control gate structure comprising a plurality of enlarged end portions, wherein at least a portion of each of the enlarged end portions is positioned under the overhang portions on adjacent floating gate structures, and wherein at least a portion of the enlarged end portion is positioned in a recess formed in an isolation structure positioned between the adjacent floating gate structures.

In yet another illustrative embodiment, the device comprises a plurality of floating gate structures formed above a semiconducting substrate, an isolation structure positioned between each of the plurality of floating gate structures and a control gate structure comprising a plurality of enlarged end portions, the entirety of each of the enlarged end portions being positioned within a recess formed in one of the isolation structures.

In a further illustrative embodiment, the device comprises a plurality of floating gate structures formed above a semiconducting substrate, an isolation structure positioned between each of the plurality of floating gate structures, each of the floating gate structures comprising overhang portions that are positioned above adjacent isolation structures, and a control gate structure comprising a main body, a plurality of downwardly-extending fingers and a plurality of enlarged end portions that are formed on a distal end of the downwardly-extending fingers, each of the enlarged end portions being positioned between adjacent floating gate structures, wherein at least a portion of each of the enlarged end portions is positioned in a recess formed in one of the isolation structures, and wherein at least a portion of each of the enlarged end portions is positioned under the overhang portions on adjacent floating gate structures.

In one illustrative embodiment, the method comprises forming a plurality of isolation structures in a semiconducting substrate, forming a plurality of floating gate structures above the substrate, each of the isolation structures being positioned between adjacent floating gate structures, performing an isotropic etching process to define a recess in each of the plurality of isolation structures and forming a control gate structure above the plurality of floating gate structures, the control gate structure comprising a plurality of enlarged end portions, each of which is at least partially positioned in one of the recesses in the isolation structures.

In another illustrative embodiment, the method comprises forming a plurality of isolation structures in a semiconducting substrate, forming a plurality of floating gate structures above the substrate, each of the isolation structures being positioned between adjacent floating gate structures, wherein forming the plurality of floating gate structures comprises forming the plurality of floating gate structures such that each of the floating gate structures comprises overhang portions that are positioned adjacent the isolation structures, performing an isotropic etching process to define a recess in each of the plurality of isolation structures and forming a control gate structure above the plurality of floating gate structures, the control gate structure comprising a plurality of enlarged end portions, each of which is entirely positioned in one of the recesses, and wherein at least a portion of the enlarged end portions are positioned under the overhang portions on adjacent floating gate structures.

In yet another illustrative embodiment, the method comprises forming a plurality of isolation structures in a semiconducting substrate, forming a plurality of floating gate structures above the substrate, each of the isolation structures being positioned between adjacent floating gate structures, wherein forming the plurality of floating gate structures comprises forming the plurality of floating gate structures such that each of the floating gate structures comprises overhang portions that are positioned adjacent the isolation structures, performing an isotropic etching process to define a recess in each of the plurality of isolation structures and forming a control gate structure above the plurality of floating gate structures, the control gate structure comprising a plurality of enlarged end portions, each of which is at least partially positioned in one of the recesses, and wherein at least a portion of the enlarged end portions are positioned under the overhang portions on adjacent floating gate structures.

### BRIEF DESCRIPTION OF THE DRAWINGS

The invention may be understood by reference to the following description taken in conjunction with the accompanying drawings, in which like reference numerals identify like elements, and in which:

FIGS. 1 and 2 are cross-sectional views of illustrative prior art memory devices taken along a longitudinal axis of a word line;

FIGS. 3A-3B are cross-sectional views of one illustrative embodiment of the present invention; and

FIGS. 4A-4D depict one illustrative method of forming the device depicted in FIGS. 3A-3B.

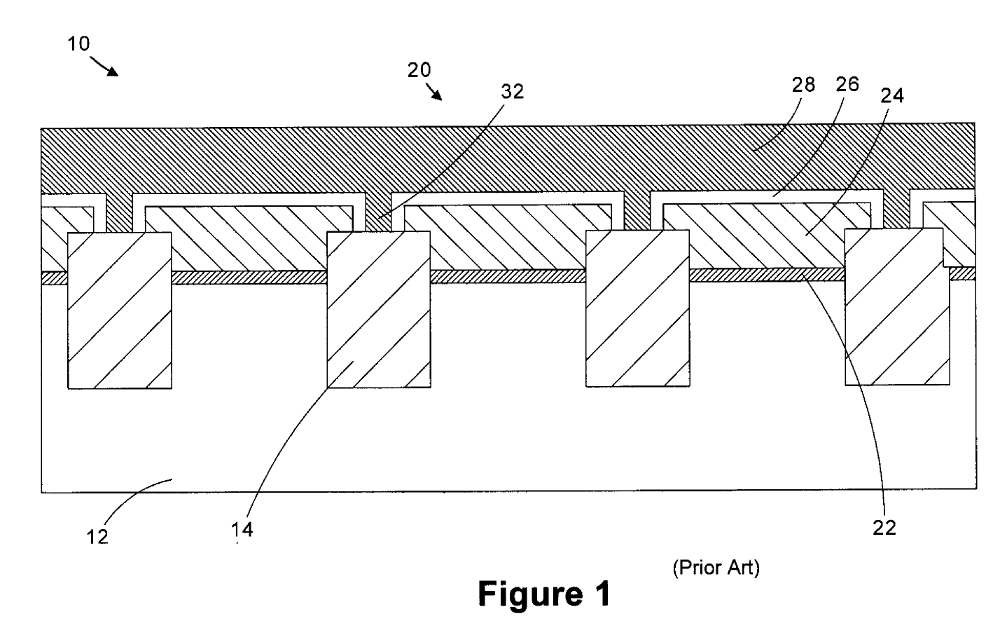

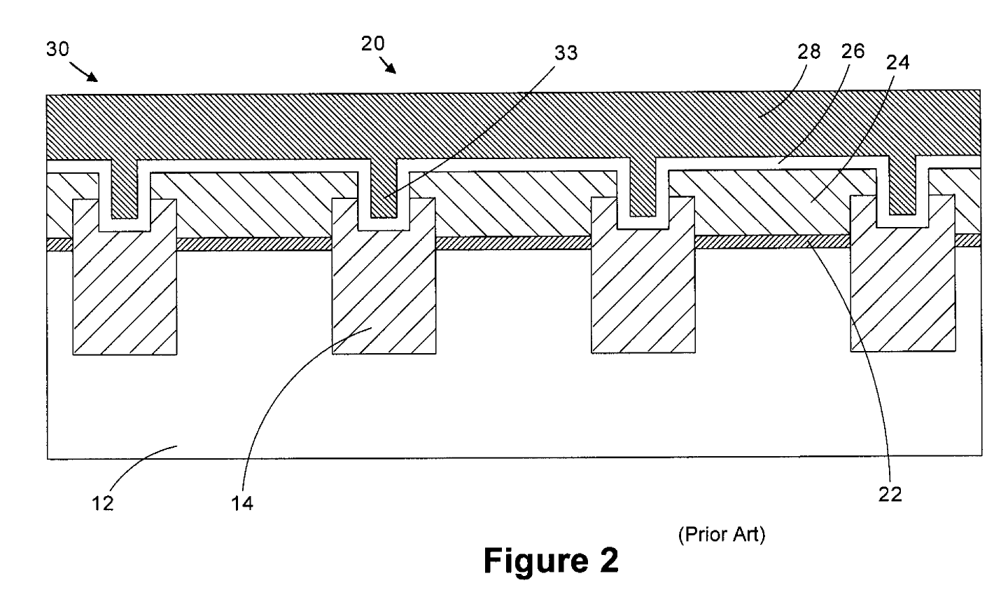

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various regions and structures of an integrated circuit device are depicted in the drawings. For purposes of clarity and explanation, the relative sizes of the various features and regions depicted in the drawings may be exaggerated or reduced as compared to the size of those features or structures on real-world integrated circuit devices. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be explicitly set forth in the specification in a definitional manner that directly and unequivocally provides the special definition for the term or phrase.

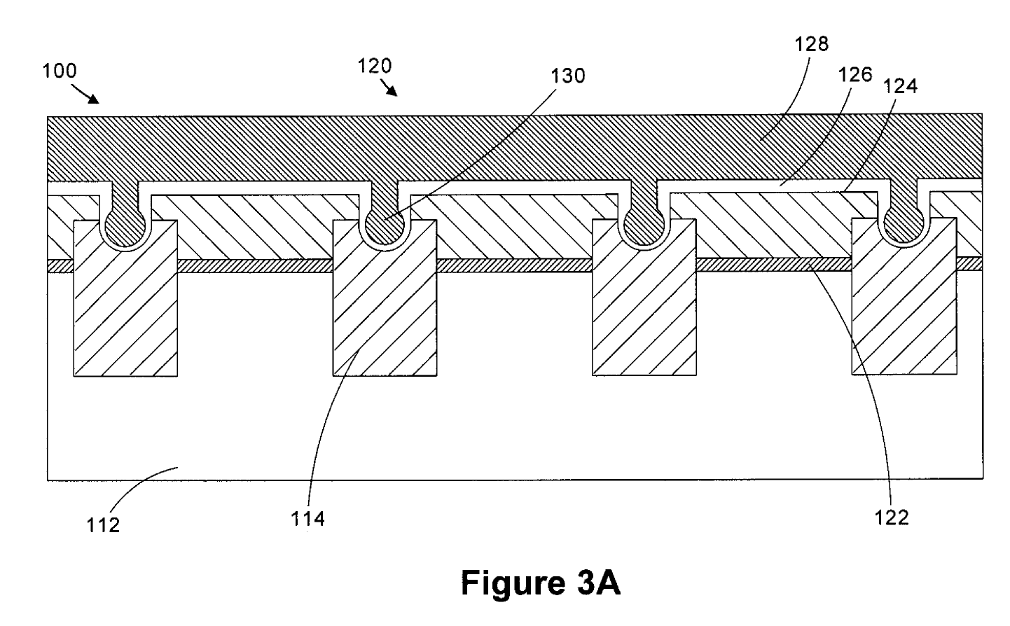

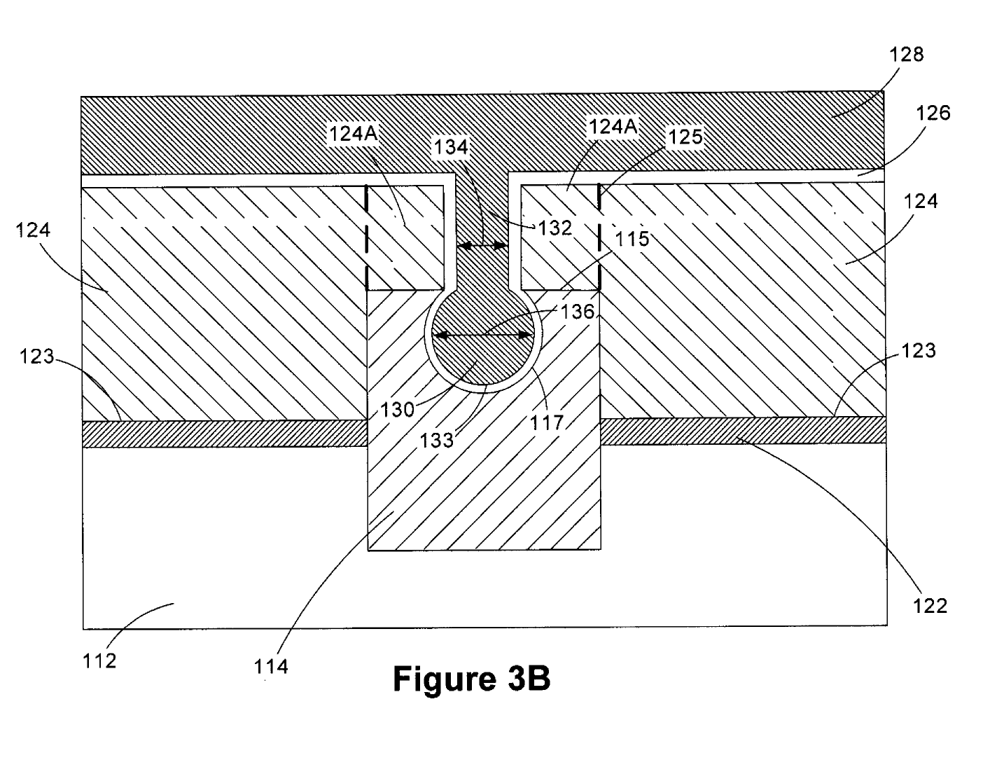

One illustrative embodiment of the memory device 100 disclosed herein is depicted in FIGS. 3A-3B. FIG. 3A is a cross-sectional view of the device 100 taken along a longitudinal axis of a word line 128 of the device 100. FIG. 3B is an enlarged view of a portion of the device 100.

The device 100 is comprised of a gate stack 120 comprising a first insulating layer 122 (sometimes referred to as a tunnel oxide layer), a floating gate 124, an inter-gate insulating layer 126 and a control gate 128. A plurality of isolation structures 114, e.g., trench isolation structures, electrically isolate the adjacent floating gates 124 and memory cells. The control gate 128 further comprises an enlarged end portion 130, at least a portion of which is positioned between adjacent floating gate structures 124. Also note that, in one illustrative embodiment, at least a portion of the enlarged end portion 130 is positioned within the recess 117 formed in the isolation structure 114. In some cases, the entirety of the enlarged end portion 130 may be positioned within the recess 117.

The device 100 may be fabricated using a variety of known materials and processing tools. For example, the substrate 112 may be a bulk silicon substrate or an epitaxial layer of silicon. The isolation structure 114 may be comprised of any type of insulating material, e.g., silicon dioxide, silicon oxynitride, etc. In one illustrative embodiment, the isolation structures 114 are trench isolation structures that may be formed using known techniques. The first insulating layer 122 may be comprised of a variety of materials, such as silicon dioxide, and it may be formed by performing known deposition or thermal growth processes. Similarly, the floating gate structures 124 may be comprised of a variety of materials, e.g., a doped polysilicon, a metal electrode, trapping materials such as high-k dielectrics (Al₂O₃, HfO₂, etc. or a combination thereof), nano-storage materials, etc. The floating gate structures 124 may be formed by performing known deposition and etching techniques. The inter-gate insulating material 126 (sometimes referred to as an inter-poly insulating layer) may also be comprised of a variety of materials. For example, the inter-gate insulating material 126 may be comprised of a layer of silicon nitride positioned between two layers of silicon dioxide (a so-called “ONO” stack). The control gate 128 may also be made from a variety of materials, e.g., a doped polysilicon, a metal electrode, trapping materials such as high-k dielectrics (Al₂O₃, HfO₂, etc. or a combination thereof), nano-storage materials, etc. As will be recognized by those skilled in the art after a complete reading of the present application, the present invention has broad applicability. For example, the present invention may be employed with SONOS type devices. Thus, the present invention should not be considered as limited to the illustrative materials and embodiments depicted herein.

FIG. 3B is an enlarged view of the enlarged end portion 130 that is positioned at least partially between adjacent floating gate structures 124. The control gate 128 comprises a downward-extending finger 132 that further comprises the enlarged end portion 130 on the distal end thereof. The portion 130 is enlarged in the sense that the horizontal dimension 136 of the enlarged end portion 130 is greater than the horizontal dimension 134 of the finger 132 when viewed in this longitudinal cross-sectional view. In one illustrative embodiment, at least a portion of the enlarged end portion 130 is positioned below the top surface 115 of the isolation structure 144. In one particularly illustrative embodiment, substantially the entirety of the enlarged end portion 130 is positioned below the top surface 115 of the isolation structure 114. In the depicted embodiment, the lower-most point 133 of the enlarged end portion 130 is positioned above the top surface 123 of the first insulating layer 122 (e.g., the tunnel oxide layer) by a distance ranging from approximately 2-5 nm.

In FIG. 3B, the enlarged end portion 130 is depicted as having a generally rounded cross-sectional configuration with a nominal diameter 136 of approximately 2-5 nm. However, it should be understood that the illustrative dimension 136 of the enlarged end portion 130 may vary depending upon the application. The inter-gate insulating layer 126 is depicted in FIG. 3B as lining the entirety of the recess 117 formed in the isolation structure 114. However, depending upon a variety of factors, the inter-gate insulating layer 126 may not cover the entirety of the inner surface of the recess 117. Also note that at least a portion of the enlarged end portion 130 is positioned under overhang portions 124A of adjacent floating gate structures 124 that is positioned above the isolation structure (defined by the dashed line 125).

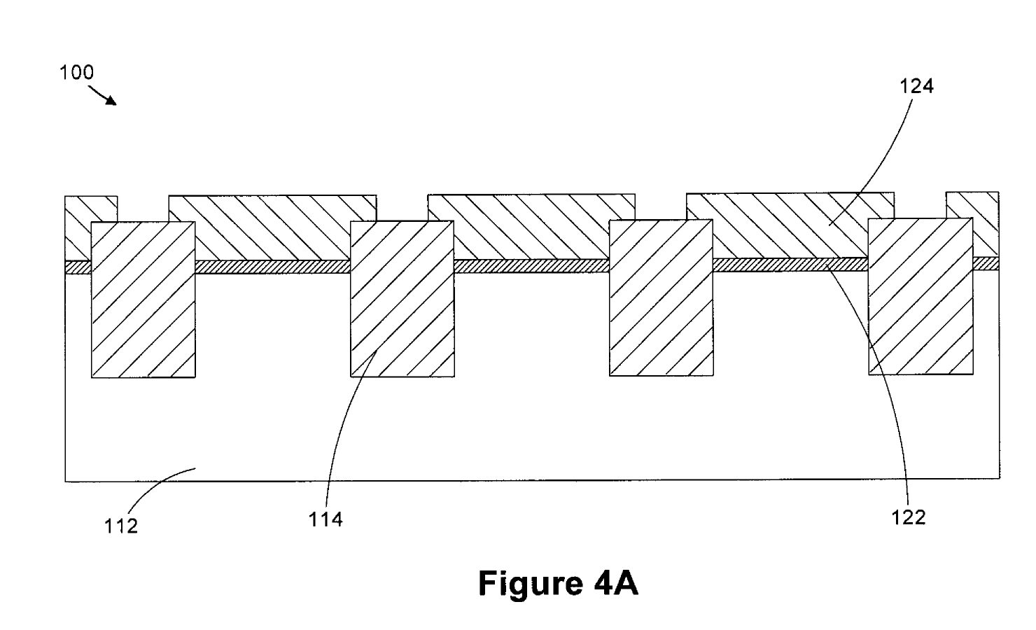

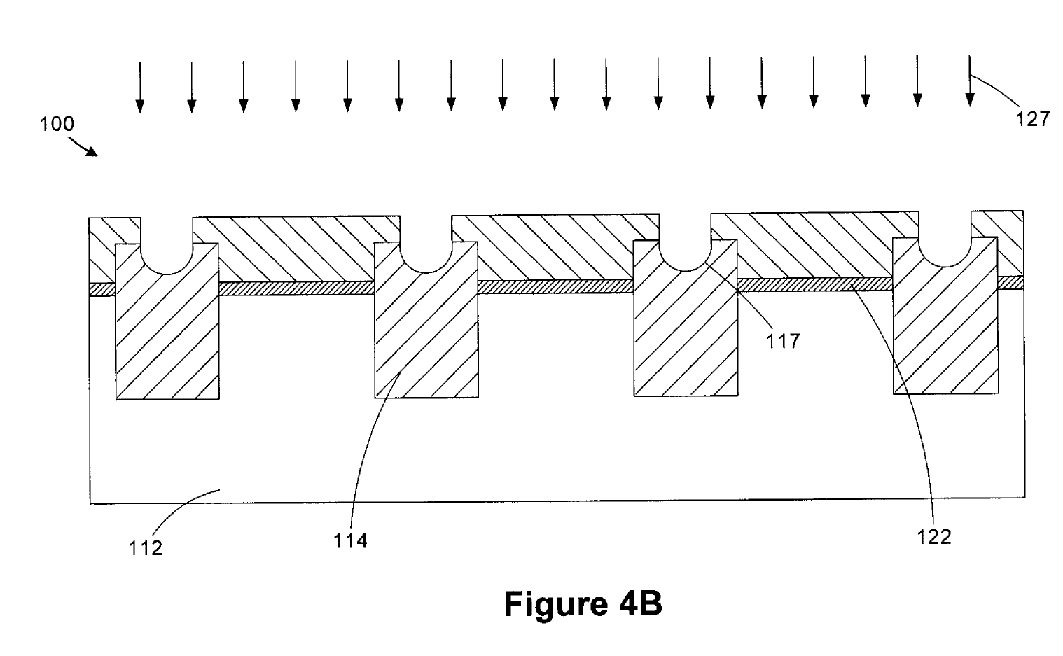

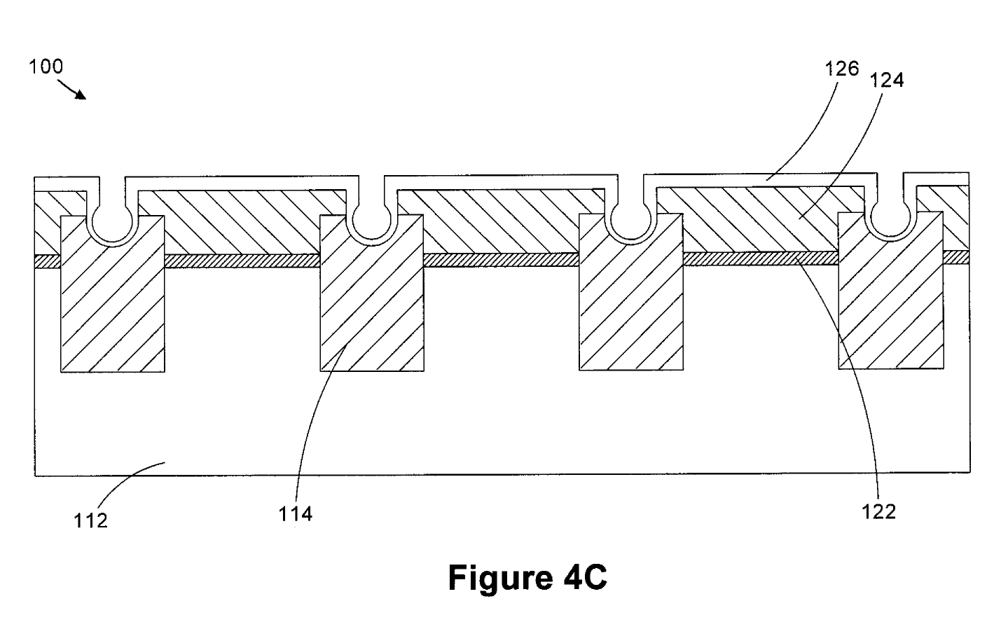

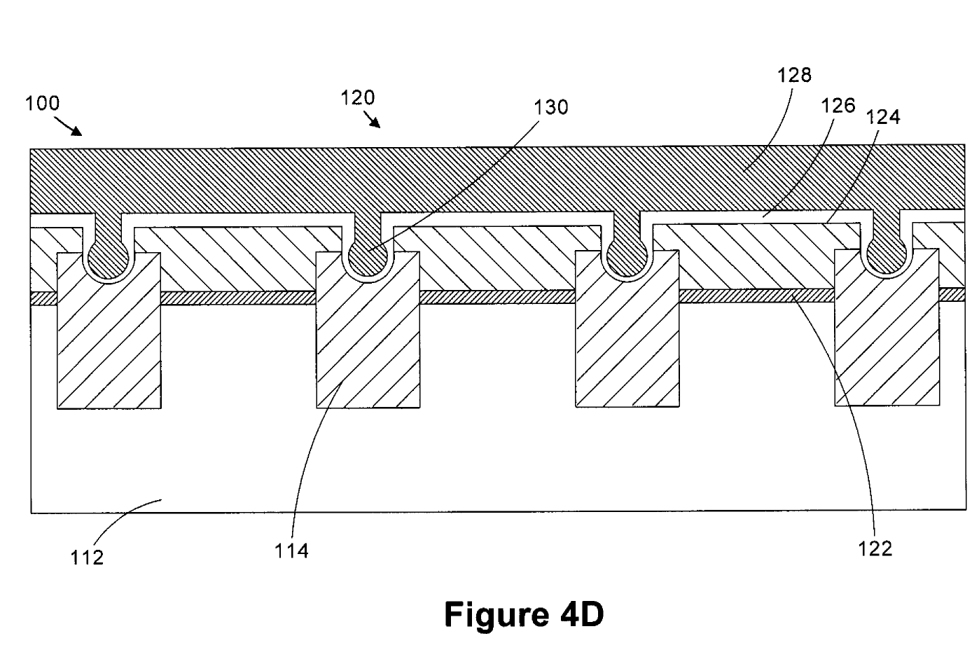

One illustrative technique for forming the device 100 will now be described with reference to FIGS. 4A-4C. As shown in FIG. 4A, a plurality of isolation structures 114 may be formed in the substrate 112 using a variety of known techniques. For example, the isolation structures 114 may be trench isolation structures that are formed by performing known etching, deposition and polishing techniques. The first layer of insulating material 122 may be formed by performing known thermal growth or deposition processes. The floating gate structure 124 may be formed by depositing a layer of polysilicon and performing an anisotropic etching process to thereby define the floating gate structures 124.

As indicated in FIG. 4B, the next step involves formation of the recess 117 in the isolation structure 114. The recess 117 is formed by performing an isotropic etching process 127 using the floating gate structures 124 as a mask. The isotropic etching process 127 may be a wet or dry etch process. In one particularly illustrative embodiment, when the isolation structure 114 is comprised of silicon dioxide, the etching process 127 is a wet[?] etching process using chemicals such as diluted HF as the etchant. The recess 117 in FIG. 4B is depicted as a semi-circular shape. However, as will be understood by those skilled in the art, the recess 117 that is actually formed on real-world devices may not have such a precise geometric shape. In some cases, the recess 117 defined by the isotropic etching process 127 may have an irregular shape. As indicated in FIG. 3B, in some cases, a portion of the recess 117 will extend under the overhang portions 124A of adjacent floating gate structures 124. The size of the recess 117, e.g., depth, width, can be controlled by controlling the parameters of the etching process 127.

Next, as shown in FIG. 4C, the inter-gate insulating layer 126 may be formed using known techniques and materials. For example, the inter-gate insulating layer 126 may be comprised of multiple layers of material, such as an ONO (oxide-nitride-oxide) layer stack that is well known to those skilled in the art. In one illustrative embodiment, a plurality of conformal deposition processes may be performed to form a multiple layer inter-gate insulating layer 126. In some cases, the inter-gate insulating layer 126 may not cover the entire inner surface of the recess 117, i.e., there may be gaps in the coverage.

Thereafter, as depicted in FIG. 4D, the control gate 128 is formed using known techniques and materials. For example, the control gate 128 may be comprised of doped polysilicon that is formed by performing a chemical vapor deposition process during which dopant material is introduced during the deposition process. Alternatively, ions may be implanted into the layer of polysilicon.

Due to the unique structure of the device 100, better capacitive coupling between the control gate 128 and the floating gate 124 may be achieved. Additionally, the novel structure disclosed herein may provide some degree of increased shielding between adjacent memory cells.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A device, comprising:
a plurality of floating gate structures formed above a semiconducting substrate;
an isolation structure positioned between each of said plurality of floating gate structures; and
a control gate structure comprising a plurality of enlarged end portions, each of said enlarged end portions being positioned between adjacent floating gate structures.

2. The device of claim 1, wherein said semiconducting substrate comprises silicon.

3. The device of claim 1, wherein said semiconducting substrate is a bulk silicon substrate.

4. The device of claim 1, wherein said isolation structure is a trench isolation structure.

5. The device of claim 1, further comprising an inter-gate insulating layer positioned between said control gate structure and each of said plurality of floating gate structures.

6. The device of claim 5, wherein said inter-gate insulating layer comprises a layer of silicon nitride positioned between two layers of silicon dioxide.

7. The device of claim 1, wherein at least a portion of said enlarged end portion is positioned in a recess formed in said isolation structure.

8. The device of claim 7, wherein said inter-gate insulating layer is positioned in said recess between an inner surface of said recess and said enlarged end portion.

9. The device of claim 1, wherein the entirety of said enlarged end portion is positioned within a recess formed in said isolation structure.

10. The device of claim 1, wherein each of said floating gate structures comprises overhang portions that are positioned above adjacent isolation structures and wherein at least a portion of said enlarged end portion is positioned under said overhang portions on adjacent floating gate structures.

11. The device of claim 1, wherein said control gate structure comprises a main body and a plurality of downwardly-extending fingers, and wherein said enlarged end portions are formed on a distal end of said downwardly-extending fingers.

12. The device of claim 11, wherein, when a longitudinal cross-section of said control gate structure is taken, said enlarged end portion has a greater lateral cross-sectional dimension than a lateral cross-sectional dimension of said downwardly-extending fingers.

13. The device of claim 1, wherein said enlarged end portions have a generally semi-circular configuration.

14. The device of claim 1, wherein a bottom of said enlarged end portion is positioned approximately 2-5 nm above a top surface of a tunnel oxide layer formed under each of said floating gate structures.

15. A device, comprising:
a plurality of floating gate structures formed above a semiconducting substrate;
an isolation structure positioned between each of said plurality of floating gate structures, wherein each of said floating gate structures comprises overhang portions that are positioned above adjacent isolation structures; and
a control gate structure comprising a plurality of enlarged end portions, wherein at least a portion of each of said enlarged end portions is positioned under said overhang portions on adjacent floating gate structures, and wherein at least a portion of said enlarged end portion is positioned in a recess formed in an isolation structure positioned between said adjacent floating gate structures.

16. The device of claim 15, further comprising an inter-gate insulating layer positioned in said recess between an inner surface of said recess and said enlarged end portion.

17. The device of claim 15, wherein the entirety of said enlarged end portion is positioned within said recess.

18. The device of claim 15, wherein said control gate structure comprises a main body and a plurality of downwardly-extending fingers, and wherein said enlarged end portions are formed on a distal end of said downwardly-extending fingers.

19. The device of claim 18, wherein, when a longitudinal cross-section of said control gate structure is taken, said enlarged end portion has a greater lateral cross-sectional dimension than a lateral cross-sectional dimension of said downwardly-extending fingers.

20. The device of claim 15, wherein a bottom of said enlarged end portion is positioned approximately 2-5 nm above a top surface of a tunnel oxide layer formed under each of said floating gate structures.

21. A device, comprising:
a plurality of floating gate structures formed above a semiconducting substrate;
an isolation structure positioned between each of said plurality of floating gate structures; and
a control gate structure comprising a plurality of enlarged end portions, the entirety of each of said enlarged end portions being positioned within a recess formed in one of said isolation structures.

22. The device of claim 21, wherein said isolation structure is a trench isolation structure.

23. The device of claim 21, further comprising an inter-gate insulating layer that is positioned in said recess between an inner surface of said recess and said enlarged end portion.

24. The device of claim 21, wherein each of said floating gate structures comprises overhang portions that are positioned adjacent said isolation structures and wherein at least a portion of said enlarged end portion is positioned under said overhang portions on adjacent floating gate structures.

25. The device of claim 21, wherein said control gate structure comprises a main body and a plurality of downwardly-extending fingers, and wherein said enlarged end portions are formed on a distal end of said downwardly-extending fingers.

26. The device of claim 25, wherein, when a longitudinal cross-section of said control gate structure is taken, said enlarged end portion has a greater lateral cross-sectional dimension than a lateral cross-sectional dimension of said downwardly-extending fingers.

27. The device of claim 21, wherein a bottom of said enlarged end portion is positioned approximately 2-5 nm above a top surface of a tunnel oxide layer formed under each of said floating gate structures.

28. A device, comprising:
a plurality of floating gate structures formed above a semiconducting substrate;
an isolation structure positioned between each of said plurality of floating gate structures, each of said floating gate structures comprising overhang portions that are positioned above adjacent isolation structures; and
a control gate structure comprising a main body, a plurality of downwardly-extending fingers and a plurality of enlarged end portions that are formed on a distal end of said downwardly-extending fingers, each of said enlarged end portions being positioned between adjacent floating gate structures, wherein at least a portion of each of said enlarged end portions is positioned in a recess formed in one of said isolation structures, and wherein at least a portion of each of said enlarged end portions is positioned under said overhang portions on adjacent floating gate structures.

29. The device of claim 28, further comprising an inter-gate insulating layer positioned between said control gate structure and each of said plurality of floating gate structures.

30. The device of claim 28, wherein said inter-gate insulating layer is positioned in said recess between an inner surface of said recess and said enlarged end portion.

31. The device of claim 28, wherein the entirety of said enlarged end portion is positioned within said recess.

32. The device of claim 28, wherein, when a longitudinal cross-section of said control gate structure is taken, said enlarged end portion has a greater lateral cross-sectional dimension than a lateral cross-sectional dimension of said downwardly-extending fingers.

33. The device of claim 28, wherein a bottom of said enlarged end portion is positioned approximately 2-5 nm above a top surface of a tunnel oxide layer formed under each of said floating gate structures.

34. A method, comprising:
forming a plurality of isolation structures in a semiconducting substrate;
forming a plurality of floating gate structures above said substrate, each of said isolation structures being positioned between adjacent floating gate structures;
performing an isotropic etching process to define a recess in each of said plurality of isolation structures; and
forming a control gate structure above said plurality of floating gate structures, said control gate structure comprising a plurality of enlarged end portions, each of which is at least partially positioned in one of said recesses in said isolation structures.

35. The method of claim 34, wherein forming a plurality of isolation structures comprises forming a plurality of trench isolation structures.

36. The method of claim 34, further comprising forming an inter-gate insulating layer positioned between said control gate structure and each of said plurality of floating gate structures.

37. The method of claim 34, further comprising forming an inter-gate insulating layer in said recess between an inner surface of said recess and said enlarged end portion.

38. The method of claim 34, wherein forming said control gate structure comprises forming said control gate structure such that an entirety of said enlarged end portion is positioned within said recess.

39. The method of claim 34, wherein forming said plurality of floating gate structures comprises forming said plurality of floating gate structures such that each of said floating gate structures comprises overhang portions that are positioned adjacent said isolation structures and wherein at least a portion of said enlarged end portion is positioned under said overhang portions on adjacent floating gate structures.

40. The method of claim 34, wherein forming said control gate structure comprises forming said control gate structure such that said control gate structure comprises a main body and a plurality of downwardly-extending fingers, and wherein said enlarged end portions are formed on a distal end of said downwardly-extending fingers.

41. The method of claim 40, wherein, forming said control gate structure comprises forming said control gate structure such that, when a longitudinal cross-section of said control gate structure is taken, said enlarged end portion has a greater lateral cross-sectional dimension than a lateral cross-sectional dimension of said downwardly-extending fingers.

42. The method of claim 34, wherein forming said control gate structure comprises forming said control gate structure such that a bottom of said enlarged end portion is positioned approximately 2-5 nm above a top surface of a tunnel oxide layer formed under each of said floating gate structures.

43. A method, comprising:
forming a plurality of isolation structures in a semiconducting substrate;
forming a plurality of floating gate structures above said substrate, each of said isolation structures being positioned between adjacent floating gate structures, wherein forming said plurality of floating gate structures comprises forming said plurality of floating gate structures such that each of said floating gate structures comprises overhang portions that are positioned adjacent said isolation structures;
performing an isotropic etching process to define a recess in each of said plurality of isolation structures; and
forming a control gate structure above said plurality of floating gate structures, said control gate structure comprising a plurality of enlarged end portions, each of which is entirely positioned in one of said recesses, and wherein at least a portion of said enlarged end portions are positioned under said overhang portions on adjacent floating gate structures.

44. The method of claim 43, wherein forming a plurality of isolation structures comprises forming a plurality of trench isolation structures.

45. The method of claim 43, further comprising forming an inter-gate insulating layer positioned between said control gate structure and each of said plurality of floating gate structures.

46. The method of claim 43, further comprising forming an inter-gate insulating layer in said recess between an inner surface of said recess and said enlarged end portion.

47. The method of claim 43, wherein forming said control gate structure comprises forming said control gate structure such that said control gate structure comprises a main body and a plurality of downwardly-extending fingers, and wherein said enlarged end portions are formed on a distal end of said downwardly-extending fingers.

48. The method of claim 47, wherein, forming said control gate structure comprises forming said control gate structure such that, when a longitudinal cross-section of said control gate structure is taken, said enlarged end portion has a greater lateral cross-sectional dimension than a lateral cross-sectional dimension of said downwardly-extending fingers.

49. A method, comprising:
forming a plurality of isolation structures in a semiconducting substrate;
forming a plurality of floating gate structures above said substrate, each of said isolation structures being positioned between adjacent floating gate structures, wherein forming said plurality of floating gate structures comprises forming said plurality of floating gate structures such that each of said floating gate structures comprises overhang portions that are positioned adjacent said isolation structures;
performing an isotropic etching process to define a recess in each of said plurality of isolation structures; and
forming a control gate structure above said plurality of floating gate structures, said control gate structure comprising a plurality of enlarged end portions, each of which is at least partially positioned in one of said recesses, and wherein at least a portion of said enlarged end portions are positioned under said overhang portions on adjacent floating gate structures.

50. The method of claim 49, wherein forming a plurality of isolation structures comprises forming a plurality of trench isolation structures.

51. The method of claim 49, further comprising forming an inter-gate insulating layer positioned between said control gate structure and each of said plurality of floating gate structures.

52. The method of claim 49, further comprising forming an inter-gate insulating layer in said recess between an inner surface of said recess and said enlarged end portion.

53. The method of claim 49, wherein forming said control gate structure comprises forming said control gate structure such that said control gate structure comprises a main body and a plurality of downwardly-extending fingers, and wherein said enlarged end portions are formed on a distal end of said downwardly-extending fingers.

54. The method of claim 53, wherein, forming said control gate structure comprises forming said control gate structure such that, when a longitudinal cross-section of said control gate structure is taken, said enlarged end portion has a greater lateral cross-sectional dimension than a lateral cross-sectional dimension of said downwardly-extending fingers.
